(19) United States
(12) Patent Application Publication
(10) Pub. No.: US 2025/0210557 A1
(43) Pub. Date: Jun. 26, 2025

(54) COMPONENT PITCH REALIGNMENT FROM BOND PAD METAL PITCH

(71) Applicant: Advanced Micro Devices, Inc., Santa Clara, CA (US)

(72) Inventors: Darryl Prudich, Ann Arbor, MI (US); Carson Donahue Henrion, Ft. Collins, CO (US); Eric Busta, Ft. Collins, CO (US); John Wuu, Ft. Collins, CO (US); Russell Schreiber, Austin, TX (US); Stephen Dussinger, Ft. Collins, CO (US)

(73) Assignee: Advanced Micro Devices, Inc., Santa Clara, CA (US)

(21) Appl. No.: 18/395,233

(22) Filed: Dec. 22, 2023

(51) Int. Cl. H01L 23/00; H01L 23/48; H01L 23/522

(52) U.S. Cl. CPC H01L 24/08; H01L 23/481; H01L 23/5226; H01L 2224/05647; H01L 2224/08145; H01L 2224/80895; H01L 2224/80896

(57) ABSTRACT

A bonded die assembly includes first conductive pads of a first substrate each bonded to respective second conductive pads of a second substrate, the first and second conductive pads arrayed at an inter-pad spacing, a plurality of active components located in the second substrate and arrayed at an inter-component spacing, and a metallization structure disposed between the first substrate and the second substrate, where the metallization structure is configured to decrease the inter-component spacing relative to the inter-pad spacing. The die assembly is characterized by an improved utilization of available device active area.

### BACKGROUND

Semiconductor devices are used in a variety of applications, such as cell phones, personal computers, digital cameras, and other electronic equipment. Semiconductor devices are typically fabricated by sequentially depositing different material layers, including insulating or dielectric layers, conductive layers, and semiconductive layers, over a semiconductor substrate, and patterning the respective layers to form circuit components therefrom. Many integrated circuits are manufactured on a single semiconductor wafer, and individual die are singulated by cutting the wafer between individual integrated circuits along a scribe line. Harvested die are typically packaged separately, in multi-chip modules, or in other types of packaging.

Ongoing efforts endeavor to improve the integration density of various electronic components (e.g., transistors, diodes, resistors, capacitors, etc.) by decreasing their minimum feature size, which allows more components to be integrated into a given area. These smaller electronic components can be incorporated into smaller packages that utilize less area than comparative packages.

In a related vein, three dimensional integrated circuits (3D ICs) have been developed where multiple semiconductor die are stacked. Example 3D IC paradigms include package-on-package (POP) and system-in-package (SiP) structures. Some 3D ICs are prepared by placing die over die at the wafer level. 3D ICs can provide improved integration density and other advantages, such as faster speeds and higher bandwidth, for instance, due to the decreased length of interconnects between the stacked die.

Hybrid bonding is one type of bonding procedure for manufacturing 3D ICs, where two semiconductor wafers are bonded together using a prescribed bonding technique. Hybrid bonds can be characterized by a bond interface that includes dielectric material-to-dielectric material bonds, and conductive material-to-conductive material bonds.

### BRIEF DESCRIPTION OF THE DRAWINGS

The accompanying drawings illustrate a number of example implementations and are a part of the specification. Together with the following description, these drawings demonstrate and explain various principles of the present disclosure.

FIG. 1 is a cross-sectional schematic view of a comparative hybrid bonded integrated circuit where plural devices or logic elements are aligned with respective bond pad metal structures or through silicon vias.

FIG. 2 is a cross-sectional schematic view of a hybrid bonded integrated circuit where the pitch amongst plural devices or logic elements is less than the pitch of a corresponding array of bond pad metal structures or through silicon vias.

FIG. 3 is a cross-sectional schematic view of a hybrid bonded integrated circuit where a device or logic element is laterally offset from a corresponding bond pad metal interface.

FIG. 4 is a flowchart of an exemplary method for manufacturing a hybrid bonded integrated circuit.

Throughout the drawings, identical reference characters and descriptions indicate similar, but not necessarily identical, elements. While the example implementations described herein are susceptible to various modifications and alternative forms, specific implementations have been shown by way of example in the drawings and will be described in detail herein. However, the example implementations described herein are not intended to be limited to the particular forms disclosed. Rather, the present disclosure covers all modifications, equivalents, and alternatives falling within the scope of the appended claims.

### DETAILED DESCRIPTION OF EXAMPLE IMPLEMENTATIONS

Fusion or direct wafer bonding allows dielectric layers, and more precisely activated functional groups, to form a bridge between wafers with the support of hydrogen bridge bonds. This pre-bonding can occur at standard temperature and pressure. During a subsequent annealing step, low-energy hydrogen bridge bonds can be converted into covalent bonds. With pre-bonding occurring at ambient conditions and supporting highly-precise alignment, 3D integration can be accomplished using wafer-to-wafer fusion bonding. Moreover, copper pads can be processed in parallel with the dielectric layers, allowing pre-bonding of the dielectric layers under ambient conditions while electrical contacts can be formed during annealing via metal diffusion bonding.

In the manufacture of 3D stacked integrated circuits, including ICs formed through hybrid bonding platforms, design rules can impose limitations on the bond pad via (BPV) pitch, as well as on the associated through silicon via (TSV) pitch within selected die. Integrated circuit architectures that map the BPV or TSV pitch to corresponding device or logic elements, however, can inefficiently utilize the available area of silicon at the device level. Disclosed herein are integrated circuit designs where driver/receiver or other logic elements within a BPV inter-die connection structure are arrayed at a tighter pitch than the BPV pitch limit. This results in a more efficient use of silicon area and decreases the area overhead of stacked die designs.

In accordance with particular implementations, a metallization structure located between driver/receiver or other logic elements and bond pad metal or through silicon via elements can be configured to decrease the pitch of the driver/receiver or other logic elements relative to the pitch of the bond pad metal or through silicon via elements. One or more metal lines within the metallization structure between the device active area and the bond pad metal or TSV structures can be extended in a transverse direction in an amount effective to realign driver/receiver or other logic elements within a device region of a hybrid bonded IC independent of the corresponding bond pad metal or TSV alignment.

A bonded die assembly includes first conductive pads of a first substrate each bonded to respective second conductive pads of a second substrate, the first and second conductive pads arrayed at an inter-pad spacing, a plurality of active components located in the second substrate and arrayed at an inter-component spacing, and a metallization structure disposed between the first substrate and the second substrate, where the metallization structure is configured to decrease the inter-component spacing relative to the inter-pad spacing.

A further bonded die assembly includes a first die including a first semiconductor substrate with an array of conductive vias extending entirely through the first semiconductor substrate, and a second die including a second semiconductor substrate with an array of active components formed in the second semiconductor substrate and a metallization layer configured to electrically connect each active component to a respective one of the conductive vias, where the metallization layer includes a laterally-extending conductive line, and a pitch of the array of active components is less than a pitch of the array of conductive vias.

In an exemplary implementation, a bonded die assembly can include a first die including a first semiconductor substrate with an array of conductive vias extending entirely through the first semiconductor substrate, and a second die including a second semiconductor substrate with an array of active components formed in the second semiconductor substrate and a metallization layer configured to electrically connect each active component to a respective one of the conductive vias, where the metallization layer includes a laterally-extending conductive line, and a pitch of the array of active components is less than a pitch of the array of conductive vias.

In some instantiations, a first end of the laterally-extending conductive line overlies a selected conductive via within the array of conductive vias and is laterally offset with respect to a selected active component within the array of active components, a second end of the laterally-extending conductive line is laterally offset with respect to the selected conductive via and overlies the selected active component, and the selected conductive via is electrically connected to the selected active component through the laterally-extending conductive line.

An exemplary method of forming a three dimensional integrated circuit includes forming a first die having a first substrate and an array of conductive vias that extend entirely through the first substrate, forming a second die having a second substrate, an array of active components in the second substrate, and a metallization structure overlying the second substrate and electrically contacting the array of active components, the first die and the second die each having a plurality of conductive pads disposed within an insulating material on a top surface thereof, and bonding the first die to the second die, where a pitch of the array of active components is less than a pitch of the array of conductive vias within the three dimensional integrated circuit. The act of bonding can include hybrid bonding although alternative bonding techniques are contemplated.

Features from any of the implementations described herein can be used in combination with one another in accordance with the general principles described herein. These and other implementations, features, and advantages will be more fully understood upon reading the following detailed description in conjunction with the accompanying drawings and claims.

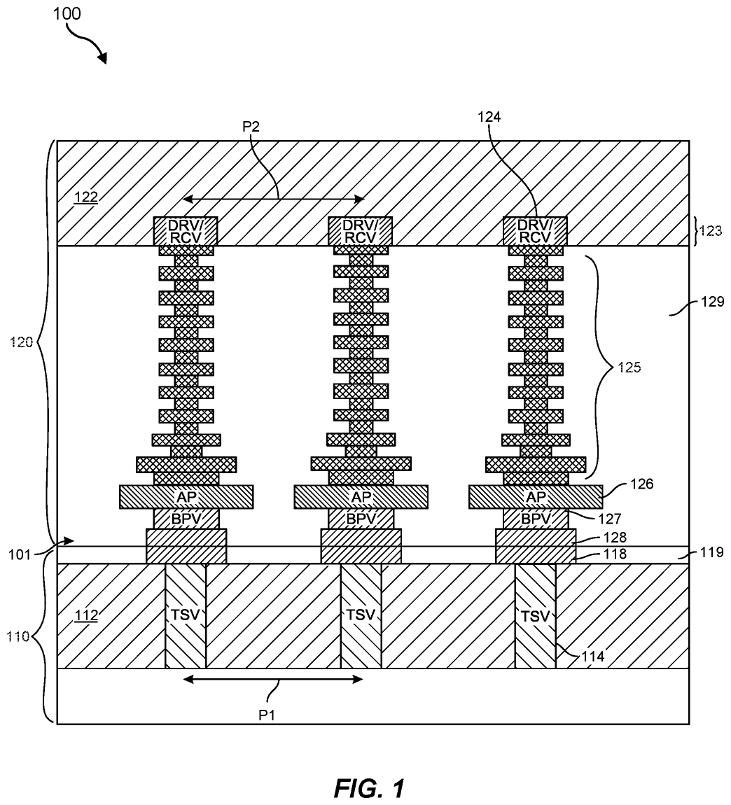

The present disclosure is directed generally to integrated circuits having an improved utilization of available device active area, and more specifically to an integrated circuit architecture where logic elements in a hybrid bonded IC are arrayed at a tighter pitch than corresponding BPV or TSV structures. Exemplary IC architectures and associated methods of manufacture are illustrated schematically in FIGS. 1-4.

Referring to FIG. 1, shown is a cross-sectional view depicting various aspects of a hybrid die stacking and packaging technology. The 3D IC structure 100 includes a bottom die 110 and a top die 120 overlying the bottom die 110. The bottom and top die 110, 120 are joined along hybrid bonding interface 101.

Bottom die 110 includes a semiconductor substrate 112. Semiconductor substrate 112 can include silicon or another semiconductor material, such as GaAs, InP, Si/Ge, or SiC, for example. In certain instantiations, the semiconductor substrate 112 can include a silicon-on-insulator (SOI) or a germanium-on-insulator (GOI) structure. Through silicon vias (TSVs) 114 extend through the semiconductor substrate 112 and are configured as vertical electrical connections that pass entirely through the semiconductor substrate 112. The TSVs support face-to-back bonding (e.g., hybrid bonding) of the bottom and top die.

Proximate to an upper surface of bottom die 110, electrical connections can be made to the TSVs 114 using, for example, a Damascene process. Such a process can include forming a bond pad metal oxide layer 119 over the semiconductor substrate 112, patterning and etching openings in the oxide layer 119 to expose the TSVs 114, forming a conductive layer over the oxide layer 119 and within the openings, and removing the conductive layer overburden to form embedded bond pad metal (BPM) contacts 118.

In accordance with various implementations, oxide layer 119 and BPM contacts 118 can be formed using any suitable deposition techniques, including, for example, chemical vapor deposition (CVD), such as low pressure chemical vapor deposition (LPCVD), physical vapor deposition (PVD), or atomic layer deposition (ALD). Chemical mechanical polishing can be used to remove excess bond pad metal. In the illustrated 3D IC structure 100, the TSVs 114 and respective bond pad metal (BPM) contacts 118 are aligned and in electrical contact, and are arrayed at pitch P1 within bottom die 110.

Referring still to FIG. 1, top die 120 includes a semiconductor substrate 122. Semiconductor substrate 122 can include silicon or another semiconductor material, such as GaAs, InP, Si/Ge, or SiC. Semiconductor substrate 122 includes a device region 123 located proximate to a surface thereof with a plurality of devices or logic elements 124 formed therein. The device/logic elements 124 can include active components or circuits, such as driver logic elements, receiver logic elements, conductive features, implantation regions, resistors, capacitors, inductors, and other semiconductor elements, including transistors, diodes, etc. The device/logic elements 124 can include driver/receiver elements, for example. Device region 123 and its constituent elements can be formed over the semiconductor substrate 122 in a front-end-of-line (FEOL) process, for example. Individual device/logic elements 124 can be electrically connected to respective through silicon vias 114 located in the bottom semiconductor substrate 112 through an intervening metallization structure and bond pad architecture.

A dielectric layer 129 can overlie device region 123 of semiconductor substrate 122 and can include a single dielectric layer or plural dielectric layers. In some implementations, the dielectric layer(s) 129 includes silicon dioxide. In some implementations, the dielectric layer(s) 129 includes a low dielectric constant (low-k) material. Dielectric layer(s) 129 can be formed using any suitable process, including CVD, PVD, or ALD, for example.

A metallization structure 125 can be disposed within the dielectric layer 129. The metallization structure 125 can be formed in a back-end-of-line (BEOL) process. The metallization structure 125 includes conductive features, such as conductive lines and vias. As will be appreciated, the metallization structure 125 can cooperate with a metallic bond pad 126, bond pad via 127, and bond pad metal (BPM) contact 128 to form electrical connections between device/logic elements 124 and respective TSVs 114 located in the bottom die 110. The conductive features 125-128 can include conductive materials typically used in BEOL processes, such as Cu, Al, W, Ti, TiN, Ta, TaN, or multiple layers or combinations thereof.

In accordance with various implementations, bond pad metal (BPM) contacts 118, 128 are disposed proximate to a surface of each respective die 110, 120 and are aligned and in electrical contact along hybrid bonding interface 101. Bond pad metal (BPM) contacts 118, 128 can include copper or a copper alloy, for example, and can be insulated from an adjacent dielectric layer (e.g., bond pad metal oxide layer 119 or dielectric layer 129) by a diffusion barrier (not shown).

In the comparative architecture of FIG. 1, the device/logic elements 124 are arrayed at a pitch P2 within top die 120 such that P2 is substantially equal to P1. That is, the device/logic elements 124 directly overlie or substantially directly overlie corresponding through silicon vias 114 and bond pad vias 127. As will be appreciated, the relatively large value(s) of P2 can amount to an under-utilization of the available area within the device region 123 of semiconductor substrate 122.

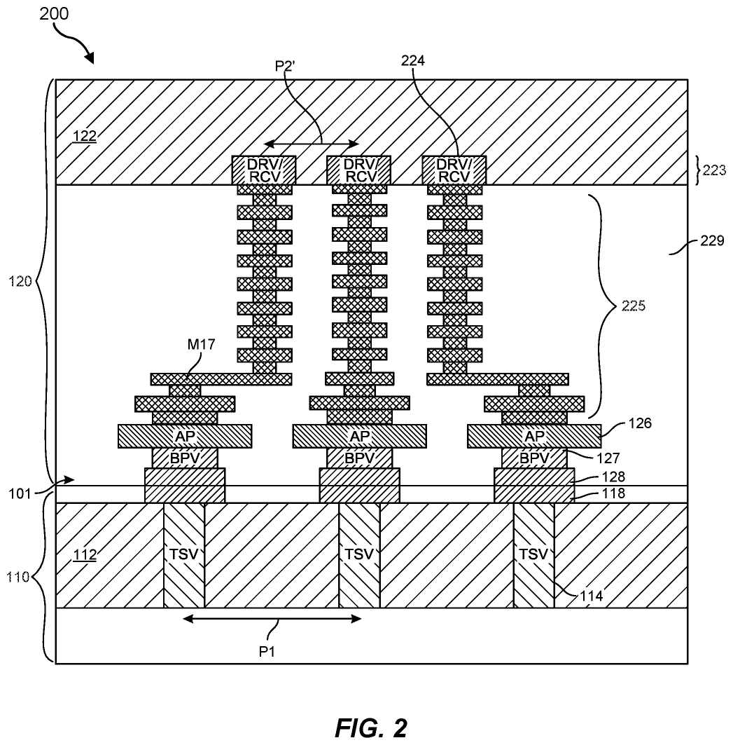

Turning to FIG. 2, shown is a cross-sectional view depicting various aspects of a hybrid die stacking and packaging technology where the metallization structure within the dielectric layer 229 of top die 120 is configured to decrease the device or logic element 224 pitch relative to the bond pad via 127 or through silicon via 114 pitch, providing better area utilization within semiconductor substrate 122.

The 3D IC structure 200 is analogous to the 3D IC structure 100 of FIG. 1 and includes bottom and top die 110, 120 that are joined along a hybrid bonding interface 101. Through silicon vias 114 located in semiconductor substrate 112 and corresponding bond pad vias 127 located in dielectric layer 229 are co-aligned and arrayed at a pitch P1. Semiconductor substrate 112 can include, for example, silicon, germanium, silicon germanium, silicon carbide, III-V compound semiconductors, or II-VI compound semiconductors.

In FIG. 2, selected metal lines (e.g., selected lines M17) within metallization structure 225 are extended laterally in an amount effective to realign driver/receiver or other logic elements 224 within the device region 223. In accordance with various implementations, by reconfiguring metallization structure 225, one or more device/logic elements 224 can be repositioned at an improved pitch P2′ such that P2′<P1. In certain instantiations, pitch P2′ can be 90% or less of pitch P1, e.g., P2′ can be 90%, 80%, 70%, 60%, or 50% of pitch P1, including ranges between any of the foregoing values. By way of example, the pitch P1 within a hybrid 3D IC structure can be greater than 10 micrometers, e.g., approximately 10 micrometers, whereas the pitch P2′ can be less than 10 micrometers, e.g., approximately 5 micrometers.

The metallization structure 225 shown is merely for illustrative purposes. The metallization structure 225 can include other configurations and can include one or more additional conductive lines and via layers, for example. Moreover, one or a combination of selected metal lines, in addition to or in lieu of selected lines M17, can be extended laterally or jogged to create a desired offset amongst selected device/logic elements 224. The 3D IC structure 200, including a pitch realignment of device/logic elements 224 relative to corresponding bond pad vias (BPVs) 127 and through silicon vias (TSVs) 114 can enable an integrated circuit having an increase in bandwidth density, allowing more data to be shuttled from memory into the cores and from storage into memory.

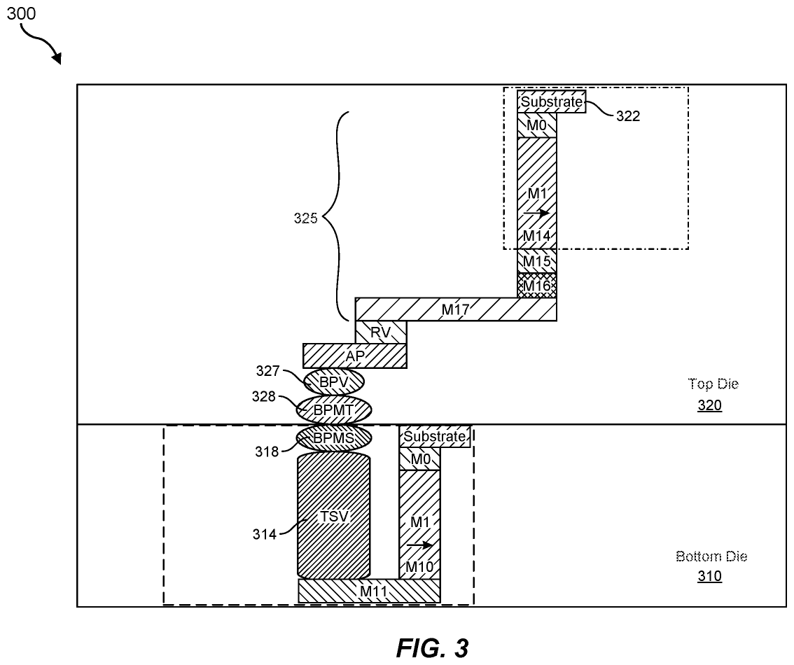

Referring to FIG. 3, shown is a further 3D IC structure in accordance with particular implementations. The 3D hybrid bonded IC structure 300 includes bottom and top die 310, 320 each having a respective inlaid bond pad metal structure 318, 328. A selected metal line M17 within metallization structure 325 is extended laterally to offset the device/logic elements within semiconductor substrate 322 relative to the bond pad via 327 and TSV structure 314.

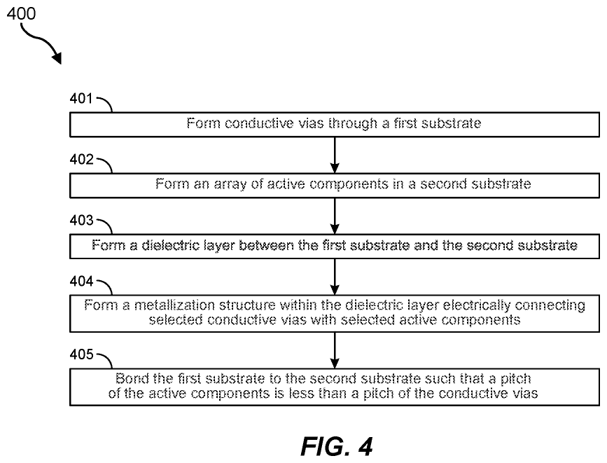

An exemplary method of manufacturing a bonded die assembly is illustrated in the flowchart of FIG. 4. The method 400 includes forming a first die including a first substrate and an array of conductive vias that extend entirely through the first substrate (401), forming a second die including a second substrate, an array of active components in the second substrate (402), forming a dielectric layer between the first and second substrates (403), forming a metallization structure within the dielectric layer electrically contacting selected conductive vias with selected active components (404), and bonding the first die to the second die to form a three dimensional integrated circuit, where a pitch of the array of active components is less than a pitch of the array of conductive vias within the three dimensional integrated circuit (405).

Conductive vias can include through silicon vias (TSVs), for example, which can be formed by patterning and creating an opening extending through the substrate and then by filling the opening with a suitable conductive material. Excess conductive material (e.g., copper, aluminum, or combinations, or alloys thereof) can be removed using a planarization process such as a chemical mechanical polishing (CMP) process.

A dielectric layer can be formed by spin coating, chemical vapor deposition (CVD), or physical vapor deposition (PVD), although further deposition processes are contemplated, and can include any suitable organic or inorganic dielectric material, including polymers materials such as benzocyclobutene (BCB) polymer, polyimide (PI), or polybenzoxazole (PBO), or silicon dioxide.

A metallization structure can include an interconnected structure formed in a back-end-of-line (BEOL) process in some implementations. Conductive portions of the metallization structure can be formed from conductive materials used in a BEOL process, such as copper (Cu), a copper alloy, aluminum (AI), an aluminum allow, or combinations thereof.

While the foregoing disclosure sets forth various implementations using specific block diagrams, flowcharts, and examples, each block diagram component, flowchart step, operation, and/or component described and/or illustrated herein can be implemented, individually and/or collectively, using a wide range of hardware, software, or firmware (or any combination thereof) configurations. In addition, any disclosure of components contained within other components should be considered example in nature since many other architectures can be implemented to achieve the same functionality.

The process parameters and sequence of steps described and/or illustrated herein are given by way of example only and can be varied as desired. For example, while the steps illustrated and/or described herein can be shown or discussed in a particular order, these steps do not necessarily need to be performed in the order illustrated or discussed. The various example methods described and/or illustrated herein can also omit one or more of the steps described or illustrated herein or include additional steps in addition to those disclosed.

The preceding description has been provided to enable others skilled in the art to best utilize various aspects of the example implementations disclosed herein. This example description is not intended to be exhaustive or to be limited to any precise form disclosed. Many modifications and variations are possible without departing from the spirit and scope of the present disclosure. The implementations disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

The term “approximately” in reference to a particular numeric value or range of values can, in certain implementations, mean and include the stated value as well as all values within 10% of the stated value. Thus, by way of example, reference to the numeric value “50” as “approximately 50” can, in certain implementations, include values equal to 50±5, i.e., values within the range 45 to 55.

The term “substantially” in reference to a given parameter, property, or condition can mean and include to a degree that one of ordinary skill in the art would understand that the given parameter, property, or condition is met with a small degree of variance, such as within acceptable manufacturing tolerances. By way of example, depending on the particular parameter, property, or condition that is substantially met, the parameter, property, or condition can be at least approximately 90% met, at least approximately 95% met, or even at least approximately 99% met.

It will be understood that when an element such as a layer or a region is referred to as being formed on, deposited on, or disposed “on” or “over” another element, it can be located directly on at least a portion of the other element, or one or more intervening elements can also be present. In contrast, when an element is referred to as being “directly on” or “directly over” another element, it can be located on at least a portion of the other element, with no intervening elements present.

While various features, elements or steps of particular implementations can be disclosed using the transitional term “comprising,” it is to be understood that alternative implementations, including those that can be described using the transitional phrases “consisting of” or “consisting essentially of,” are implied. Thus, for example, implied alternative implementations to a semiconductor substrate that comprises or includes silicon include implementations where a semiconductor substrate consists essentially of silicon and implementations where a semiconductor substrate consists of silicon.

What is claimed is:

1. A bonded die assembly comprising:
a pad architecture comprising first conductive pads of a first substrate each bonded to respective second conductive pads of a second substrate, the first and second conductive pads arrayed at an inter-pad spacing;
a plurality of active components located in the second substrate and arrayed at an inter-component spacing; and
a metallization structure disposed between the pad architecture and the plurality of active components, wherein the metallization structure is configured to decrease the inter-component spacing relative to the inter-pad spacing.

2. The bonded die assembly of claim 1, wherein the metallization structure comprises at least one conductive line extending laterally by an amount effective to decrease the inter-component spacing relative to the inter-pad spacing.

3. The bonded die assembly of claim 1, wherein the metallization structure electrically connects a selected one of the active components with a selected one of the first conductive pads such that the selected active component is laterally offset from the selected first conductive pad.

4. The bonded die assembly of claim 1, wherein the inter-component spacing is at least approximately 10% less than the inter-pad spacing.

5. The bonded die assembly of claim 1, wherein the inter-pad spacing is greater than approximately 10 micrometers and the inter-component spacing is less than approximately 8 micrometers.

6. The bonded die assembly of claim 1, wherein the active components comprise driver or receiver logic elements.

7. The bonded die assembly of claim 1, wherein the first and second conductive pads comprise bond pad metal structures.

8. The bonded die assembly of claim 1, wherein the first and second conductive pads comprise copper.

9. The bonded die assembly of claim 1, wherein the first substrate comprises conductive vias extending entirely through the first substrate and each aligned with a respective one of the first conductive pads.

10. A bonded die assembly comprising:
a first die comprising a first semiconductor substrate with an array of conductive vias extending entirely through the first semiconductor substrate; and
a second die comprising a second semiconductor substrate with an array of active components formed in the second semiconductor substrate and a metallization layer configured to electrically connect each active component to a respective one of the conductive vias, wherein the metallization layer comprises a laterally-extending conductive line, and a pitch of the array of active components is less than a pitch of the array of conductive vias.

11. The bonded die assembly of claim 10, wherein a first end of the laterally-extending conductive line overlies a selected conductive via within the array of conductive vias and is laterally offset with respect to a selected active component within the array of active components, a second end of the laterally-extending conductive line is laterally offset with respect to the selected conductive via and overlies the selected active component, and the selected conductive via is electrically connected to the selected active component through the laterally-extending conductive line.

12. The bonded die assembly of claim 10, wherein the first and second die are bonded with a hybrid bond.

13. The bonded die assembly of claim 10, wherein the first and second die are bonded with a face-to-back hybrid bond.

14. The bonded die assembly of claim 10, wherein the active components comprise driver or receiver logic elements.

15. The bonded die assembly of claim 10, wherein the pitch of the array of active components is at least approximately 10% less than the pitch of the array of conductive vias.

16. The bonded die assembly of claim 10, wherein the pitch of the array of conductive vias is greater than approximately 10 micrometers.

17. The bonded die assembly of claim 10, wherein the pitch of the array of active components is less than approximately 8 micrometers.

18. A method comprising:
forming a first die comprising a first substrate and an array of conductive vias that extend entirely through the first substrate;
forming a second die comprising a second substrate, an array of active components in the second substrate, and a metallization structure overlying the second substrate and electrically contacting the array of active components, the first die and the second die each having a plurality of conductive pads disposed within an insulating material on a top surface thereof; and
bonding the first die to the second die to form a three dimensional integrated circuit, wherein a pitch of the array of active components is less than a pitch of the array of conductive vias within the three dimensional integrated circuit.

19. The method of claim 18, wherein the metallization structure electrically connects a selected conductive via within the array of conductive vias to a selected active component within the array of active components, the metallization structure comprising a laterally-extending conductive line having a first end overlying the selected conductive via and laterally offset from the selected active component, and a second end laterally offset from the selected conductive via and overlying the selected active component.

20. The method of claim 18, wherein the bonding comprises forming a first bond between the insulating material of the first die and the insulating material of the second die, and forming a second bond between the plurality of conductive pads of the first die and the plurality of conductive pads of the second die.
